(19) United States
(12) Patent Application Publication
(10) Pub. No.: US 2006/0105555 A1
(43) Pub. Date: May 18, 2006

(54) Display apparatus and control method thereof

(76) Inventors: Dong-eog Kim, Suwon-si (KR); Sang-Jin Choi, Yongin-si (KR); Jong-han Oh, Yongin-si (KR)

Correspondence Address: STANZIONE & KIM, LLP, 919 18TH STREET, N.W., SUITE 440, WASHINGTON, DC, 20006, US

(21) Appl. No.: 11/146,061

(22) Filed: Jun. 7, 2005

(30) Foreign Application Priority Data
Jun. 25, 2004 (KR) 2004-48117

(51) Int. Cl. H01L 27/01

(52) U.S. Cl. 438/584

(57) ABSTRACT

A gantry apparatus includes a pair of first guides disposed parallely each other, a pair of sliders respectively coupled to the pair of first guides to move together with the first guides; a second guide coupled to the pair of sliders to move along the sliders; a head coupled to the second guide to move together with and along the second guide; and a rotary unit provided between the sliders and the second guide and rotating the second guide with respect to a shaft line, the shaft line being perpendicular to the moving directions of the sliders and the head. The gantry apparatus can adjust a movement of the head in diverse directions.

### CROSS-REFERENCE TO RELATED APPLICATIONS

This application claims the benefit of Korean Patent Application No. 2004-0048117, filed on Jun. 25, 2004, in the Korean Intellectual Property Office, the disclosure of which is incorporated herein by reference.

### BACKGROUND OF THE INVENTION

1. Field of the Invention

The present general inventive concept relates to a gantry apparatus, and more particularly, to a gantry apparatus improved in a moving structure of a head thereof.

2. Description of the Related Art

Generally, a gantry apparatus is employed to a scanning or deposition process for a semiconductor wafer or a glass for a liquid crystal display (LCD).

This conventional gantry apparatus comprises a head comprising a scanner to scan the glass for the LCD, and a conveyer unit transferring the head along an X-axis and a Y-axis.

With this configuration, the conventional gantry apparatus transfers the head to the X-axis and the Y-axis to test the glass for LCD. Further, the glass for LCD or the semiconductor wafer has an align mark marked thereon and thus the scanning process is operated referring thereto.

However, the conventional gantry apparatus has a difficulty in alignment because the conventional gantry apparatus does not comprise a separate device to align a movement of the head to the align mark if the head is dislocated.

Thus, it is necessary to develop a new gantry apparatus capable of adjusting the movement of the head in diverse directions.

### SUMMARY OF THE INVENTION

Accordingly, it is an aspect of the present general inventive concept to provide a gantry apparatus capable of adjusting a movement of a head in diverse directions.

Additional aspects and advantages of the present general inventive concept will be set forth in part in the description which follows and, in part, will be obvious from the description, or may be learned by practice of the general inventive concept.

The foregoing and/or other aspects and advantages of the present general inventive concept may be achieved by providing a gantry apparatus comprising a pair of first guides disposed parallely each other; a pair of sliders respectively coupled to the pair of first guides to move along the first guides; a second guide coupled to the pair of sliders to move along the sliders; a head coupled to the second guide to move together with and along the second guide; and a rotary unit provided between the sliders and the second guide to rotate the second guide with respect to a line being perpendicular to moving directions of the sliders and the head.

According to an aspect of the present general inventive concept, the rotary unit may comprise a driving part provided in one of the sliders and the second guide, and a driving contacting part coupled to the other one thereof to rotate the second guide while being driven in contact with the driving part.

According to another aspect of the present general inventive concept, the driving part may comprise a driving motor and a rotator to rotate by the driving motor, and the driving contact part is in contact with the rotator.

According to yet another aspect of the present general inventive concept, the rotator may comprise a pinion, and the driving contact part may comprise an arc shaped rack to be engaged with the pinion.

According to still another aspect of the present general inventive concept, the rotator may comprise a roller, and the driving contact part may comprise an arc shaped roller guide to be engaged with the roller.

According to another aspect of the present general inventive concept, the rotary unit further comprises a hinge rotatably coupling a side of the second guide to the slider.

According to another aspect of the present general inventive concept, the rotary unit may comprise a driving motor provided between a first side of the second guide and the slider coupled to the first side of the second guide to rotate the second guide; and an arc shaped guider provided in one of a second side of the second guide and the slider coupled to the second side of the second guide, and slidingly coupled to the other one thereof.

According to another aspect of the present general inventive concept, the guider may be provided in the slider coupled to the second side of the second guide, and slidably support the second side of the second guide.

According to another aspect of the present general inventive concept, the second side of the second guide is provided a guide projection to be guided by the guider.

### BRIEF DESCRIPTION OF THE DRAWINGS

These and/or other aspects and advantages of the present general inventive concept will become apparent and more readily appreciated from the following detailed description, taken in conjunction with the accompanying drawings of which:

FIG. 1 is a perspective view of a gantry apparatus according to an embodiment of the present general inventive concept;

FIG. 2 is an exploded perspective view of the gantry apparatus in FIG. 1;

FIG. 3 is a perspective view of an operation of a first guide and a head of the gantry apparatus in FIG. 1;

FIG. 4 is a perspective view of an operation of a second guide of the gantry apparatus in FIG. 1;

FIG. 5 is a perspective view of a gantry apparatus according to another embodiment of the present general inventive concept;

FIG. 6 is an exploded perspective view of the gantry apparatus in FIG. 5; and

FIG. 7 is a perspective view of an operation of a second guide of the gantry apparatus in FIG. 5.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

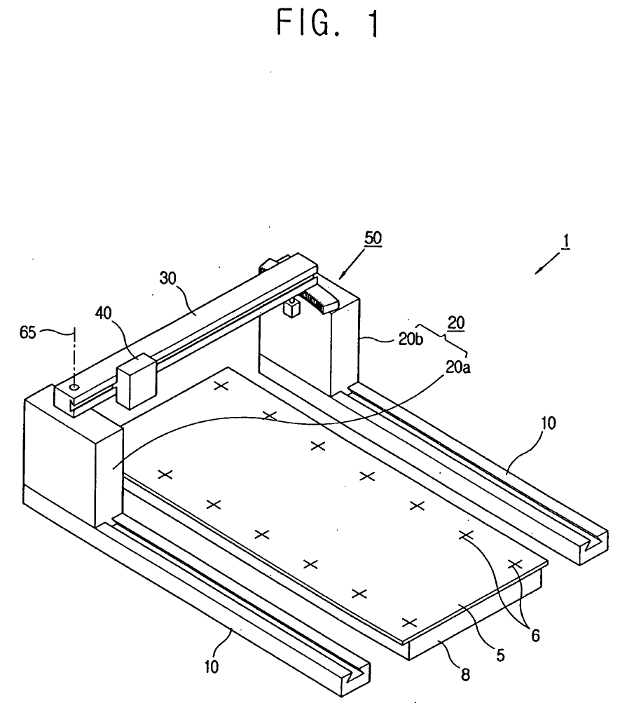

As shown in FIGS. 1 through 4, a gantry apparatus 1 according to an embodiment of the present general inventive concept may comprise a pair of first guides 10 parallelly disposed each other; a pair of sliders 20 respectively coupled to the pair of first guides 10 to move along the pair of first guides 10; a second guide 30 coupled to the pair of sliders 20 to move along the pair of sliders 20; a head 40 coupled to the second guide 30 to move together with and along the second guide 30; and a rotary unit 50 provided between one of the pair of sliders 20 and the second guide 30 to rotate the second guide 30 about a shaft line 65 vertically corresponding to a moving direction of the pair of sliders 20 and a moving direction of the head 40. Further, the gantry apparatus 1 according to an embodiment of the present general inventive concept may comprise a working platform 8 provided between the pair of first guides 10 to mount a product 5 such as a semiconductor wafer or a glass LCD thereon.

The working platform 8 may be of a flat type to mount the product 5 thereon. The working platform 8 may be provided as a conveyer belt capable of mounting and transferring the product 5.

The product 5 may comprise the semiconductor wafer or the glass for LCD to be tested through a scanning process or a deposition process. However, the product 5 may be variously transformed depending on a scanner or a deposition unit provided in the head 40. The product 5 can be marked with a plurality of align marks 6 for the scanning process or the deposition process, and the processes can be operated with reference to the plurality of align marks 6.

The pair of first guides 10 corresponds to the pair of sliders 20, and the working platform 8 can be disposed therebetween. However, the first guide 10 may be provided as a singular or more than three to support the sliders 20. The pair of first guides 10 can be parallelly disposed and can guide the pair of sliders 20 to move in the same direction.

In the first guide 10 may be provided a first accommodator 11 corresponding to a first protuding portion 21 of the slider 20.

The first accommodator 11 may be grooved in an upper surface of the first guide 10 to accommodate the first protuding portion 21 therein and thereby to guide the slider 20 precisely. However, the first accommodator 11 may be formed in the slider 20, and the first protruding portion 21 may be formed on the upper surface of the first guide 10 to be accommodated in the first accommodator 11. The first accommodator 11 may be formed as a cross sectional shape of a triangle as an example, but it may be formed as cross sectional shapes of various figures such as a rectangle, a semicircle, and so on.

The slider 20 can be provided in a pair corresponding to the pair of first guides 10. However, the slider 20 may be provided as a singular or more than three depending on the number of the first guides 10 so as to be slidingly movable thereon. The pair of slides 20 can be guided by the pair of first guides 10 to slidingly move together with the first guide 10 along a longitudinal direction of the first guide 10. In the slider 20 may be provided the first protruding portion 21 corresponding to the first accommodator 11 of the first guide 10. The slider 20 may be moved along the first guide 10 by a driving unit (not shown). This driving unit may comprise a linear motor to generate a linear movement from linearly aligning general motors, or a ball screw and a motor to rotate the ball screw, the ball screw being coupled to the slider 20 and the first guide 10, to slidingly move the slider 20 on the first guide 10.

The first protruding portion 21 may protrude from a bottom surface of the slider 20 to be accommodated in the first accommodator 11 of the first guide 10, and thus guided by the first guide 10. The first protruded portion 21 may be formed as a cross sectional shape of a triangle as an example, but it may be formed as cross sectional shapes of various figures such as a rectangle, a semicircle, and so on.

The second guide 30 can be coupled to the pair of sliders 20 to slidingly move together with the pair of sliders 20 on the first guide 10. The second guide 30 may be shaped as a long rectangular pole, but it may be formed as cross sectional shapes of various figures such as a rectangle, a semicircle, and so on. A first side 30a and a second side 30b of the second guide 30 can be respectively coupled to the pair of sliders 20. The first side 30a of the second guide 30 can be rotatably coupled to an upper portion of a first slider 20a by a hinge 61 of a rotary unit 50 (to be described later). The second side 30b of the second guide 30 can be coupled to an upper portion of a second slider 20b and becomes rotatable with respect to the hinge 61 by a driving unit 51 and a driving contact part 58 (to be described later) of the rotary unit 50. The second guide 30 supports the head 40 to be guided along a longitudinal direction of the second guide 30. In the second guide 30 is provided a second accommodator 31 corresponding to a second protruding portion 41 (to be described later) of the head 40.

The second accommodator 31 may be grooved in a side of the second guide 30 to accommodate the second protruding portion 41 of the head 40 therein and thereby to guide it precisely. An aspect of the second accommodator 31 is the same as that of the first accommodator 11 of the first guide 10, and therefore a description thereof will be omitted. However, the second accommodator 31 may be formed in the head 40, and the second protruding portion 41 may be formed in the second guide 30 to be accommodated in the second accommodator 31.

The head 40 can be coupled to the second guide 30 to be movable along the longitudinal direction of the second guide 30. In the head 40 may be provided the second protruding portion 41 corresponding to the second accommodator 31. Like the slider 20, the head 40 may be moved along the second guide 30 by a driving unit (not shown). This driving unit may comprise a linear motor to generate a linear movement from linearly aligned general motors, or a ball screw and a motor to rotate the ball screw, the ball screw being coupled to the head 40 and the second guide 30 to slidingly move the head 40 along the second guide 30. The head 40 may comprise a scanner or a deposition unit for the scanning process or the deposition process of the product 5. The head 40 can detect the plurality of align marks 6 marked on the product 5 and thus checks whether the head 40 is correctly aligned to the plurality of align marks 6 on the product 5. An alignment of the head 40 and the plurality of align marks 6 on the product 5 can be matched by moving the head 40 in the longitudinal direction of the first guide 10 or in the longitudinal direction of the second guide 30. After that, if the head 40 is dislocated about a certain degree from the plurality of align marks 6, the rotary unit 50 can be driven to rotate the second guide 30 about the certain degree to align the head 40 to the plurality of align marks 6 of the product 5.

The second protruding portion 41 may protrude from a side of the head 40 to be accommodated in the second accommodator 31 of the second guide 30 and guided by the second guide 30. The second protruded portion 41 may be formed as a cross sectional shape of a triangle as an example, but it may be formed as cross sectional shapes of various figures such as a rectangle, a semicircle, and so on.

The rotary unit 50 may comprise the driving unit 51 provided in one of the slider 20 and the second guide 30, and the driving contact part 58 provided in the other to rotate the second guide 30 while being driven in contact with the driving unit 51 to drive the second guide 30. The rotary unit 50 may further comprise the hinge 61 rotatably connecting the first side 30a of the second guide 30 and the slider 20. In other words, the hinge 61 of the rotary unit 50 may be provided between the first side 30a of the second guide 30 and the first slider 20a, and the driving unit 51 and the driving contact part 58 of the rotary unit 50 may be provided between the second side 30b of the second guide 30 and the second slider 20b.

In an embodiment of the present general inventive concept the driving unit 51 can be provided in the second slider 20b, but it may be provided in the second side 30b of the second guide 30. The driving unit 51 may comprise a rotator 55 and a driving motor 53 to rotate the rotator 55.

The driving motor 53 can generate a rotation force, and may be coupled to the second slider 20b by a coupling device, such as a bolt (not shown), and integrally moved with the second slider 20b. However, the driving motor 53 may be coupled to the second side 30b of the second guide 30.

The rotator 55 may be coupled to the driving motor 53 through a rotation shaft 54 to rotate according to the rotation force of the driving motor 53. The rotator 55 may be provided as a pinion to be engaged with the driving contact part 58, but it may also be provided as a roller contacted to the driving contact part 58 while being rolled thereon.

The driving contact part 58 can be in contact with the rotator 55, and may be coupled to the second side 30b of the second guide 30 by a coupling device such as a bolt (not shown). However, the driving contact part 58 may also be coupled to the slider 20b in accordance with the driving unit 51. The driving contact part 58 can be engaged with the pinion of the rotator 55, and may comprise an arc shaped rack. Or, the driving contact part 58 may be provided as an arc shaped roller guide so as to be contacted to the rotator 55 while being rolled thereon. Here, if the driving motor 53 provided in the second slider 20b rotates the rotator 55, the driving contact part 58 coupled to the second side 30b of the second guide 30 is moved to rotate the second guide 30 with respect to the shaft line 65.

The hinge 61 can be provided between the first side 30a of the second guide 30 and the first slider 20a, and rotatably supports the second guide 30. The hinge 61 may comprise a hinge pin accommodator 63 provided in the first side 30a of the second guide 30 to accommodate a hinge pin 62 therein.

The hinge pin 62 may be provided in the first slider 20a, or it may be provided in the first side 30a of the second guide 30. A shaft line of the hinge pin 62 may be the same as the shaft line 65 with respect to the moving direction of the slider 20 and the moving direction of the head 40. The moving direction of the slider 20 and the moving direction of the head 40 may or may not be perpendicular. Further, the shaft line 65 of the hinge 62 may or may not be perpendicular to the moving direction of the slider 20 and the moving direction of the head 40.

The hinge pin accommodator 63 may be provided in the first side 30a of the second guide 30, but it may also be provided in the first slider 20a depending on the hinge pin 62. Further, the hinge pin accommodator 63 is rotatable to the hinge pin 62, but it may rotate against a friction force.

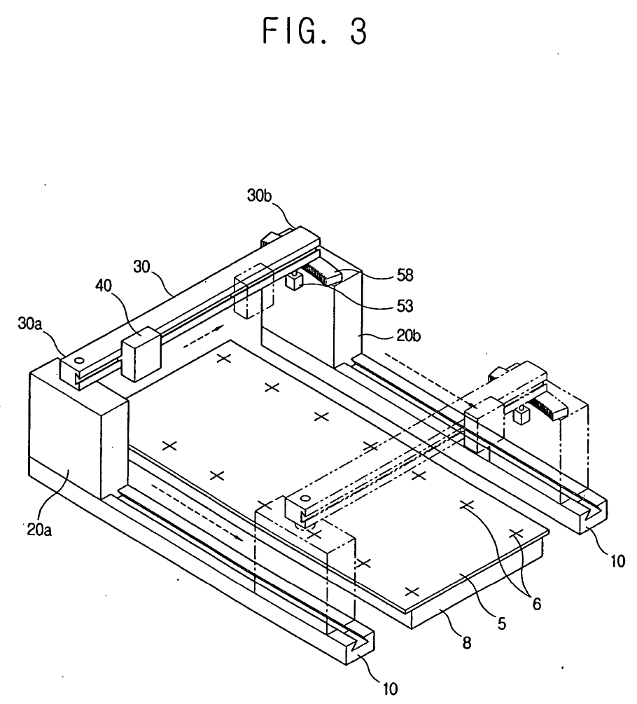

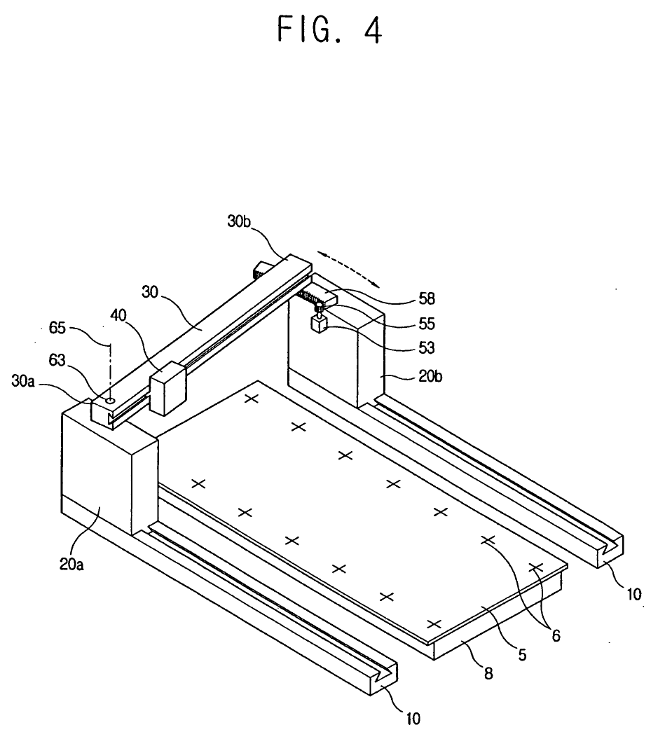

With this configuration, the gantry apparatus according to this embodiment of the present general inventive concept operates as follows, with reference to FIGS. 3 and 4.

First, the pair of sliders 20a and 20b can move along the longitudinal direction of the first guide 10, and the head 40 can be moved along the longitudinal direction of the second guide 30 by the driving unit (not shown). During the movement of the head 40 along the longitudinal direction of the first guide 10 and the longitudinal direction of the second guide 30, it is checked whether the head 40 is correctly aligned to the align marks 6 on the product 5. If the head 40 is dislocated about a certain degree from the align marks 6, the head 40 and the plurality of align marks 6 can be aligned correctly by rotating the second guide 30 about the certain degree using the rotary unit 50. In other words, the driving motor 53 of the rotary unit 50 is driven to rotate the rotator 55 so as to allow the driving contact part 58 to integrally rotate together with the second guide 30 and the head 40 with respect to the hinge pin 62.

Thus, the gantry apparatus 1 according to the an aspect of the present general inventive concept can adjust a movement of the head 40 in diverse directions by making the head 40 to be movable in the longitudinal directions of the first guide 10 and the second guide 30, and rotatable with respect to the first side 30a of the second guide 30. Further, the head 40 can be simply aligned to the align marks 6 on the product 5 because the head 40 can be moved in the diverse directions.

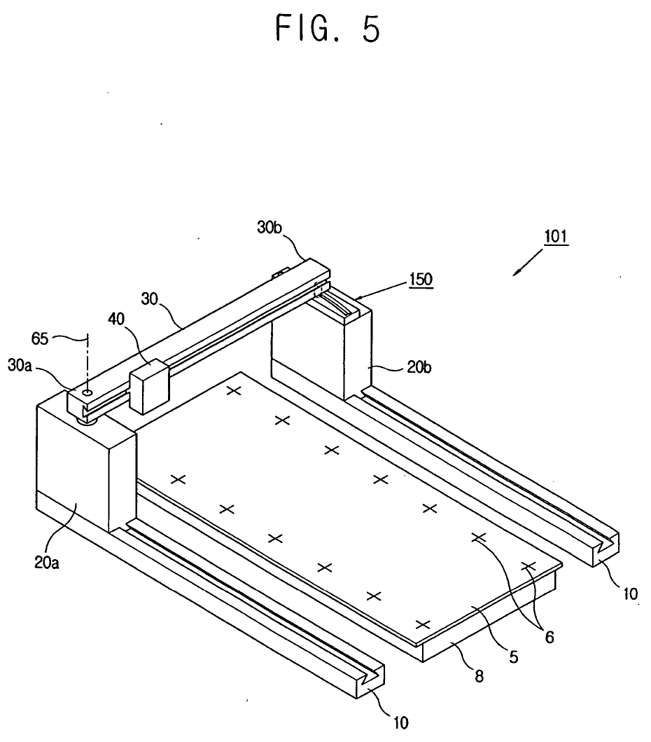

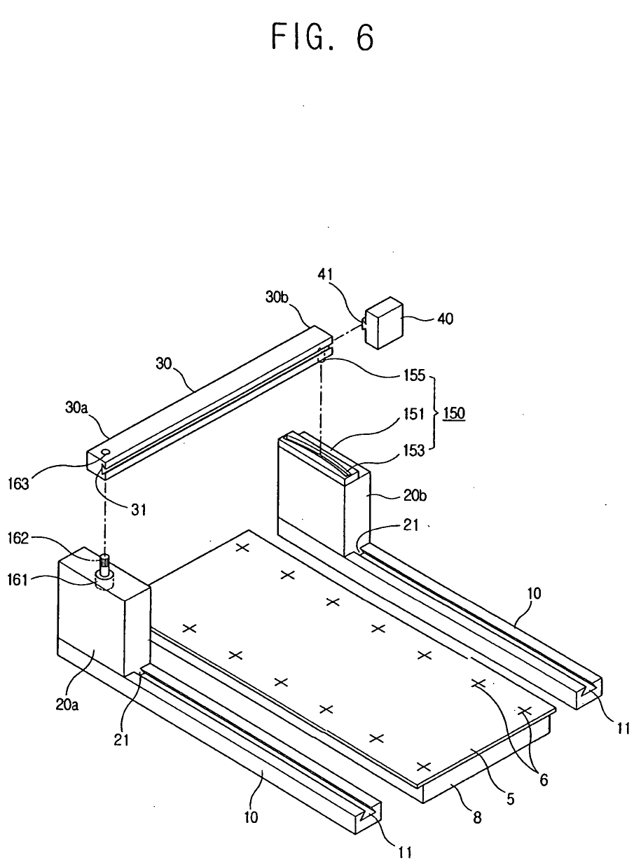

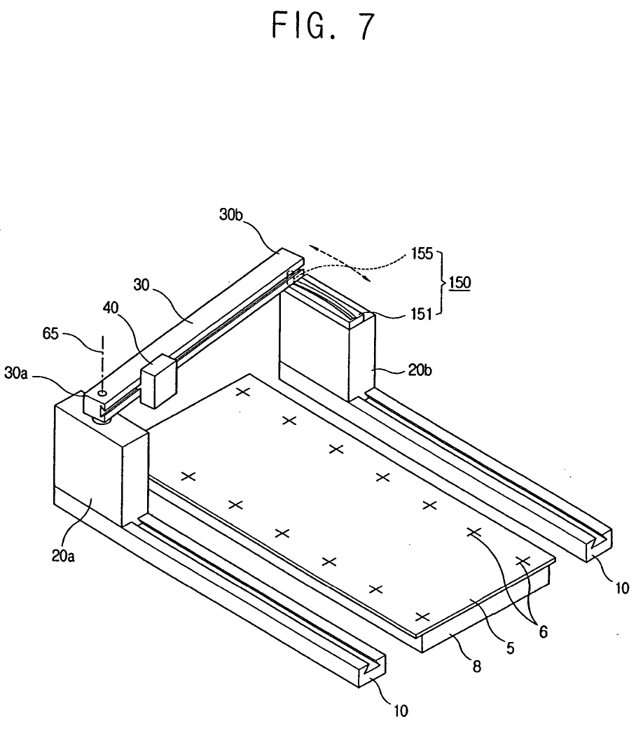

As shown in FIGS. 5 through 7, a rotary unit 150 of a gantry apparatus 101 according to another embodiment of the present general inventive concept may comprise a driving motor 161 provided between a first side 30a of a second guide 30 and a first slider 20a, and rotating the second guide 30 such that the second embodiment differs from the first embodiment. The rotary unit 150 can be provided in one of a second side 30b of the second guide 30 and a second slider 20b, and may further comprise an arc shaped guider 151 slidingly coupled to the other one of the second side 30b of the second guide 30 and the second slider 20b.

The driving motor 161 may be coupled to one of the first side 30a of the second guide 30 and the first slider 20a coupled thereto so as to rotate the second guide 30. The driving motor 161 can be coupled to the first slider 20a, and can move together with the first slider 20a. Further, in the first side 30a of the second guide 30 may be provided a rotation shaft coupling part 163 where a rotation shaft 162 of the driving motor 161 is integrally coupled so as to rotate integrally with the rotation shaft 162. However, the driving motor 161 may be provided in the first side 30a of the second guide 30 and the rotation shaft coupling part 163 may be provided in the first slider 20a.

The guider 151 may be provided in the second slider 20b and coupled to the second side 30b of the second guide 30 so as to slidingly support the second side 30b of the second guide 30. The guider 151 may be coupled to the second slider 20b by a coupling device such as a bolt (not shown). In the guider 151 may be provided an arc shaped guide groove 153 accommodating a guide projection 155 (will be described later) provided on the second side 30b of the second guide 30.

The guide projection 155 may be provided in the second side 30b of the second guide 30 to be guided by the guider 151. In other words, the guide projection 155 is engaged with the guide groove 153 of the guider 151 coupled to the second slider 20b, and guided by the guider 151. In the guide projection 155 may be provided a rolling contact roller (not shown) with respect to the guider 151.

With this configuration, the gantry apparatus 101 according to this embodiment of the present general inventive concept operates as follows.

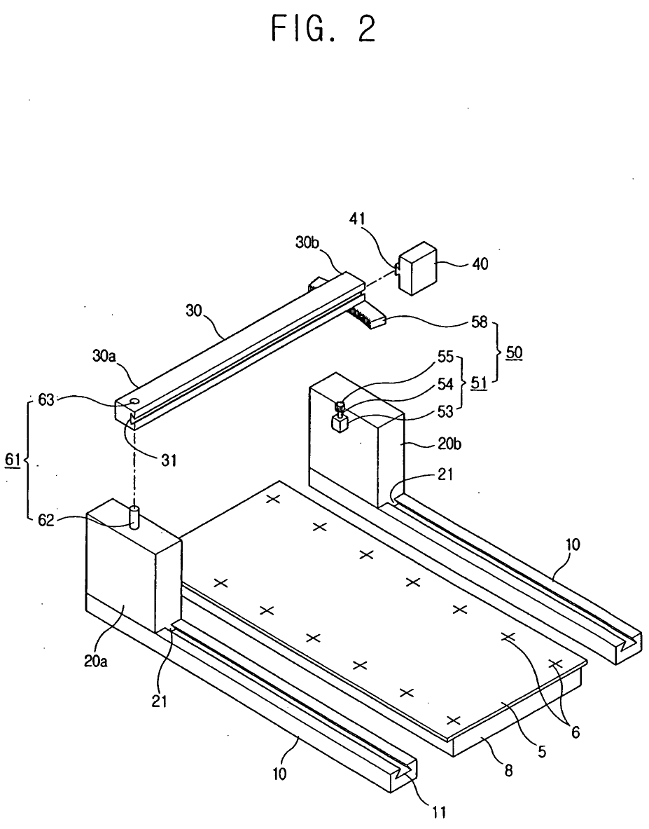

First, as described in the previous embodiment of the present general inventive concept shown in FIGS. 1 and 2, the head 40 is moved along the longitudinal direction of the first guide 10 and the longitudinal direction of the second guide 30 to check whether the head 40 is correctly aligned to the align marks 6 on the product 5. Further, if the head 40 is dislocated about a certain degree from the align marks 6, the head 40 and the plurality of align marks 6 can be aligned correctly by rotating the second guide 30 about the certain degree using the rotary unit 150. In other words, the driving motor 161 of the rotary unit 150 is driven to rotate the second guide 30 and the head 40 with respect to the rotation shaft 162 of the driving motor 161.

Thus, the gantry apparatus according to this embodiment of the present gerenal inventive concept can adjust movement of the head 40 in diverse directions by making the head 40 movable in the longitudinal directions of the first guide 10 and the second guide 30 and rotatable with respect to the first side 30a of the second guide 30. Further, the head 40 can be simply aligned to the align marks 6 on the product 5 because the head 40 can be moved in the diverse directions.

Although an embodiment of the present general inventive concept has been shown and described, the present general inventive concept is not limited to the described embodiment. Instead, it would be appreciated by those skilled in the art that changes may be made in the embodiment without departing from the principles and spirit of the general inventive concept, the scope of which is defined by the claims and their equivalents.

What is claimed is:

1. A gantry apparatus comprising:
a pair of first guides disposed parallely each other;
a pair of sliders respectively coupled to the pair of first guides to move along the first guides;
a second guide coupled to the pair of sliders to move together with sliders;
a head coupled to the second guide to move together with and along the second guide; and
a rotary unit provided between the sliders and the second guide to control the second guide to rotate with respect to a line being perpendicular to moving directions of the sliders and the head.

2. The gantry apparatus according to claim 1, wherein the rotary unit comprises a driving unit provided in one of one of the pair of sliders and the second guide, and a driving contacting part coupled to the other one thereof to control the second guide to rotate while being driven in contact with the driving part.

3. The gantry apparatus according to claim 2, wherein the driving unit comprises a rotator, and a driving motor to rotate the rotator, and the driving contact part is in contact with the rotator.

4. The gantry apparatus according to claim 3, wherein the rotator comprises a pinion, and the driving contact part comprises an arc shaped rack to be engaged with the pinion.

5. The gantry apparatus according to claim 2, wherein the rotary unit further comprises a hinge rotatably coupling a side of the second guide to the one of the pair of sliders.

6. The gantry apparatus according to claim 3, wherein the rotator comprises a roller, and the driving contact part comprises an arc shaped roller guide to be engaged with the roller.

7. The gantry apparatus according to claim 1, wherein the second guide comprises a first side and a second side, and the rotary unit comprises:
a driving motor provided between the first side of the second guide and the slider coupled to the first side of the second guide to rotate the second guide; and
an arc shaped guider provided in one of the second side of the second guide and the slider coupled to the second side of the second guide, to be coupled to the other one thereof.

8. The gantry apparatus according to claim 7, wherein the guider is provided in the slider coupled to the second side of the second guide, to slidably support the second side of the second guide.

9. The gantry apparatus according to claim 8, wherein a guide projection is formed on the second side of the second guide to be guided by the guider.

10. The gantry apparatus according to claim 1, further comprising a working platform between the pair of first guides to mount a product on.

11. The gantry apparatus according to claim 10, wherein the product comprises one of a semiconductor and a glass for a liquid crystal display (LCD).

12. The gantry apparatus according to claim 1, wherein each slider comprises a protruding portion, and each first guide comprises an accommodator to accommodate the protruding portion and to guide each a corresponding one of the sliders.

13. The gantry apparatus according to claim 1, wherein the head comprises a protruding portion, and the second guide comprises an accommodator to accommodate the protruding portion and to guide the head.

14. The gantry apparatus according to claim 1, wherein the head comprises at least one of a scanner and a deposition unit.

15. A gantry apparatus comprising:
a pair of first guides disposed parallely each other;
a pair of sliders respectively coupled to the pair of first guides to move along the first guides in a first direction;
a second guide coupled to the pair of sliders to move together with the pair of sliders in the first direction;
a head coupled to the second guide to move together with the second guide in the first direction and movably disposed on the second guide to move along the second guide in a second direction; and
a rotary unit disposed between the second guide and the sliders to move the second guide and the head in a third direction.

16. The apparatus according to claim 15, wherein the first and second directions are linear directions and the third is a curved direction.

17. The apparatus according to claim 16, wherein the third direction is a curved direction with respect to a line being perpendicular to the first direction and the second direction.

18. The gantry apparatus according to claim 15, wherein the rotary unit comprises a driving unit provided in one of one of the pair of sliders and the second guide, and a driving contacting part coupled to the other one thereof to control the second guide to rotate while being driven in contact with the driving part.

19. The gantry apparatus according to claim 18, wherein the driving unit comprises a rotator, and a driving motor to rotate the rotator, and the driving contact part is in contact with the rotator.

20. The gantry apparatus according to claim 19, wherein the rotator comprises a pinion, and the driving contact part comprises an arc shaped rack to be engaged with the pinion.

21. The gantry apparatus according to claim 19, wherein the rotator comprises a roller, and the driving contact part comprises an arc shaped roller guide to be engaged with the roller.

22. The gantry apparatus according to claim 19, wherein the rotary unit further comprises a hinge rotatably coupling a side of the second guide to one of the pair of sliders.

23. The gantry apparatus according to claim 15, wherein the second guide comprises a first side and a second side, and the rotary unit comprises:
a driving motor provided between the first side of the second guide and the slider coupled to the first side of the second guide to rotate the second guide; and
an arc shaped guider provided in one of the second side of the second guide and the slider coupled to the second side of the second guide, to be coupled to the other one thereof.

24. The gantry apparatus according to claim 23, wherein the guider is provided in the slider coupled to the second side of the second guide, to slidably support the second side of the second guide.

25. The gantry apparatus according to claim 24, wherein a guide projection is formed on the second side of the second guide to be guided by the guider.

26. A method of aligning a head of a gantry apparatus, the method comprising:
transferring a head in a longitudinal direction of a pair of first guides by moving a pair of sliders respectively coupled to the pair of first guides along the pair of first guides;
transferring the head in a longitudinal direction of a second guide coupled to the pair of sliders by moving the head coupled to the second guide along the second guide; and
rotating the second guide with respect to a line perpendicular to the moving directions of the sliders and the head so that the head is correctly aligned to a plurality if align marks on a product.

27. The method according to claim 26, wherein the rotating of the second guide comprises:
controlling a driving motor coupled to one of the sliders to rotate a rotator attached to the driving motor;
driving a driving contact part in contact with the rotator and coupled to a second side of the second guide; and
causing the second guide to rotate with respect to a hinge pin rotatably coupling a first side of the second guide and the corresponding slider.

28. The method according to claim 26, wherein the rotating of the second guide comprises:
controlling a driving motor provided between a first side of the second guide and the slider coupled to the first side of the second guide to rotate the second guide; and
guiding the second guide with an arc shaped guider provided in one of a second side of the second guide and the slider coupled to the second side of the second guide, and slidingly coupled to the other one thereof.
